(19) United States
(12) Patent Application Publication
(10) Pub. No.: US 2011/0116568 A1
(43) Pub. Date: May 19, 2011

(54) BLOCK-CODED GROUP MODULATION METHOD AND TRANSMITTER/RECEIVER USING THE SAME

(75) Inventors: Mi Kyung OH, Gyeongju-si (KR); Hyung Soo Lee, Daejeon (KR); Jae Young Kim, Daejeon (KR)

(73) Assignee: Electronics and Telecommunications Research Institute, Daejeon (KR)

(21) Appl. No.: 12/897,144

(22) Filed: Oct. 4, 2010

(30) Foreign Application Priority Data
Nov. 19, 2009 (KR) 10-2009-0112257

(51) Int. Cl. H04L 27/00; H04L 27/06; H03M 5/00

(52) U.S. Cl. 375/295; 375/340; 341/52

(57) ABSTRACT

A block-coded group modulation method includes generating a symbol by grouping at least one bit of a data bit stream into one group, classifying the symbol into an n number of sections, and generating an n number of initial information bits. Next, the method includes setting up the size of a pulse corresponding to signal energy transmitted through each of the n sections, generating an additional information bit on the basis of the number of cases according to the sequence of the energy sizes, and generating final information bits by inserting the additional information bit into the initial information bits.

### CROSS-REFERENCE TO RELATED APPLICATION

This application claims priority to and the benefit of Korean Patent Application No. 10-209-0112257 filed in the Korean Intellectual Property Office on Nov. 19, 2009, the entire contents of which are incorporated herein by reference.

### BACKGROUND OF THE INVENTION

(a) Field of the Invention

The present invention relates to a block-coded group modulation method and a transmitter and a receiver using the same. More particularly, the present invention relates to a block-coded group modulation method based on the sequence of signal energy, and a transmitter/receiver using the same.

(b) Description of the Related Art

A recent wireless technique of an impulse radio ultra-wideband (IR-UWB) method has been in the spotlight as a promising candidate technique of the physical layer of IEEE 802.15.6 on-body communication, which is the international standard of a WBAN (wireless body area network), because of the merits of low power consumption and no interference with other systems.

WBAN on-body communication must have a data rate extended from a level of about 10 Kbps to a level of 10 Mbps within a body area of 3 m. To perform reliable data communication in a wireless environment using an impulse, channel coding for detecting and correcting an error that may occur in wireless must be performed. However, such channel coding causes a problem that the data throughput is reduced, and so it is difficult to construct a transmitting/receiving termination having the data rate of a maximum level of 10 Mbps in a wireless communication network such as the WBAN.

The above information disclosed in this Background section is only for enhancement of understanding of the background of the invention and therefore it may contain information that does not form the prior art that is already known in this country to a person of ordinary skill in the art.

### SUMMARY OF THE INVENTION

The present invention has been made in an effort to provide a block-coded group modulation method and a transmitter and a receiver using the same having an advantage of increasing data throughput even though channel coding is used when data communication is performed in wireless communication systems.

An exemplary embodiment of the present invention provides a block-coded group modulation method including generating a symbol by grouping at least one bit of a data bit stream into one group, classifying the symbol into an n number of sections and generating an n number of initial information bits, setting up a size of a pulse corresponding to signal energy transmitted through each of the n sections, generating an additional information bit on the basis of the number of cases according to a sequence of the sizes, and generating final information bits by inserting the additional information bit into the initial information bits.

Another exemplary embodiment of the present invention provides a transmitter using the block-coded group modulation method, including

a grouping unit for generating a symbol by grouping at least one bit of a data bit stream into one group and generating final information bits by inserting an additional information bit into initial information bits, generated by classifying the symbol into an n number of sections, on the basis of a sequence of a size of a pulse corresponding to signal energy transmitted through each of the n sections, a mapping unit for mapping at least one bit, included in the final information bits, and the sequence, a processing unit for changing energy sizes of transmission signals corresponding to the mapping result, and a communication unit for outputting the transmission signals according to the sequence of the energy sizes.

Yet another exemplary embodiment of the present invention provides a receiver for receiving a signal from a transmitter using the block-coded group modulation method based on the sequence of signal energy, including

a detection unit for detecting pulse energy in each of pulse sections included in the received signal, a determining unit for determining a bit for the pulse energy detected in the pulse section, a demapping unit for demapping the determined bit on the basis of the sequence of signal energy, and a degrouping unit for restoring a data bit stream on the basis of the demapping result.

### BRIEF DESCRIPTION OF THE DRAWINGS

FIG. 1 is a diagram showing a typical pulse position modulation method;

FIG. 2 is a diagram showing a modulation method in which a pulse position modulation method and a pulse amplitude modulation method are combined;

FIG. 3 is a diagram showing an example in which two symbols are subject to group modulation on the basis of a block-coded group modulation method according to an exemplary embodiment of the present invention;

FIG. 4 is a diagram showing an example in which consecutive signals are modulated according to the block-coded group modulation method according to an exemplary embodiment of the present invention;

FIG. 5 is a flowchart schematically illustrating the block-coded group modulation method according to an exemplary embodiment of the present invention;

FIG. 6 is a block diagram showing a transmitter and a receiver according to an exemplary embodiment of the present invention; and

FIG. 7 is a diagram showing an example in which signals are output with different energy sizes according to an exemplary embodiment of the present invention.

### DETAILED DESCRIPTION OF THE EMBODIMENTS

In the following detailed description, only certain exemplary embodiments of the present invention have been shown and described, simply by way of illustration. As those skilled in the art would realize, the described embodiments may be modified in various different ways, all without departing from the spirit or scope of the present invention. Accordingly, the drawings and description are to be regarded as illustrative in nature and not restrictive. Like reference numerals designate like elements throughout the specification.

In the entire specification, unless explicitly described to the contrary, the word “comprise” and variations such as “comprises” or “comprising” will be understood to imply the inclusion of stated elements but not the exclusion of any other elements.

Hereinafter, a block-coded group modulation method and a transmitter and a receiver using the same according to some exemplary embodiments of the present invention are described with reference to the accompanying drawings.

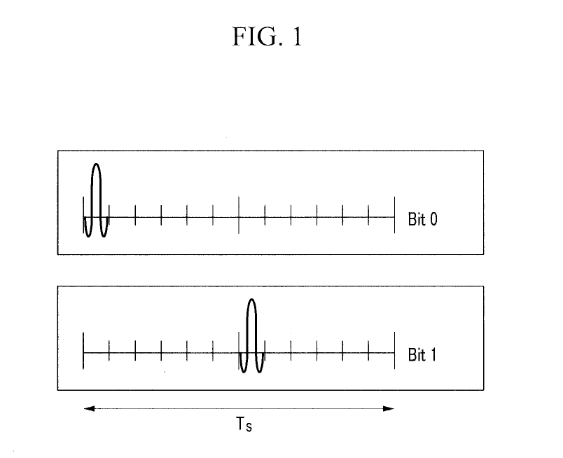

FIG. 1 is a diagram showing a typical pulse position modulation method.

First, a modulation method which is most widely used, from among modulation methods using an impulse, is a pulse position modulation (hereinafter referred to as “PPM”) method.

Referring to FIG. 1, the PPM method is a method of dividing one symbol (Tₛ) section into two sections, and mapping a bit 0 to a corresponding symbol when there is a pulse in the former section and a bit 1 to a corresponding symbol when there is a pulse in the latter section. In the typical PPM method, 1 bit is mapped to one symbol section.

Meanwhile, in the case in which one symbol section is classified into a plurality of sections, several bits can be transmitted in one symbol section. For example, in the case in which one symbol section is classified into four sections, 2 bits can be transmitted in one section.

Although the symbol is illustrated to be modulated using the PPM method, the symbol can be modulated using certain pulse signals discontinuously generated in the time domain.

Further, a group pulse position modulation (hereinafter referred to as “GPPM”) method is not a method of grouping a plurality of symbols into one symbol unit like the PPM method, but is a method of grouping a plurality of symbols into an n number of symbol units. Accordingly, the GPPM method has a data rate that makes it possible to transmit bits more than N bits, and can increase the amount of information that can be transmitted for the same time, as compared with the PPM method

The number of combinations Pₙ in which pulses that can be generated when the number of groups is generalized to n in the GPPM method are disposed can be found using the following Equation 1.

$${P}_{N} = ( \begin{matrix}2 \times N \\ N\end{matrix} ) = \frac{2 N \times ( 2 N - 1 ) \times … \times ( N - 1 )}{N \times … \times 2 \times 1} \qquad ( Equation 1 )$$

In other words, in the case in which n bits are grouped and transmitted according to the GPPM method, a log₂ Pₙ number of bits can be transmitted.

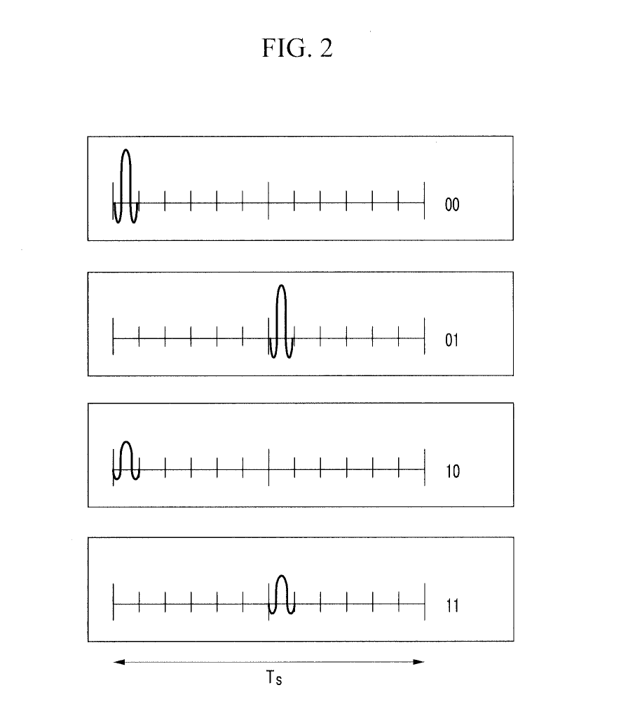

A modulation method in which the PPM method and a pulse amplitude modulation method are combined is described in detail below with reference to FIG. 2.

FIG. 2 is a diagram showing the modulation method in which the PPM method and the pulse amplitude modulation method are combined.

First, the pulse amplitude modulation (hereinafter referred to as “PAM”) method is a method of changing only the amplitude according to a signal wave with the width and cycle of a pulse being fixed. The PAM method uses a simple modulator and a simple demodulator, but it is problematic in that the output including noise is generated when the noise is introduced.

To solve the problem, information is transmitted using the modulation method in which the PPM method and the PAM method are combined. In the modulation method in which the PPM method and the PAM method are combined, in the case in which one symbol (Tₛ) section is divided into 2 sections, 2 bits can be transmitted in each section. For example, referring to FIG. 2, a total of 4 bits can be transmitted during the two symbol sections.

However, the modulation method in which the PPM method and the PAM method are combined is problematic in that a process of a receiving termination restoring the size of signal energy itself and restoring information on the basis of the restoration result is complicated.

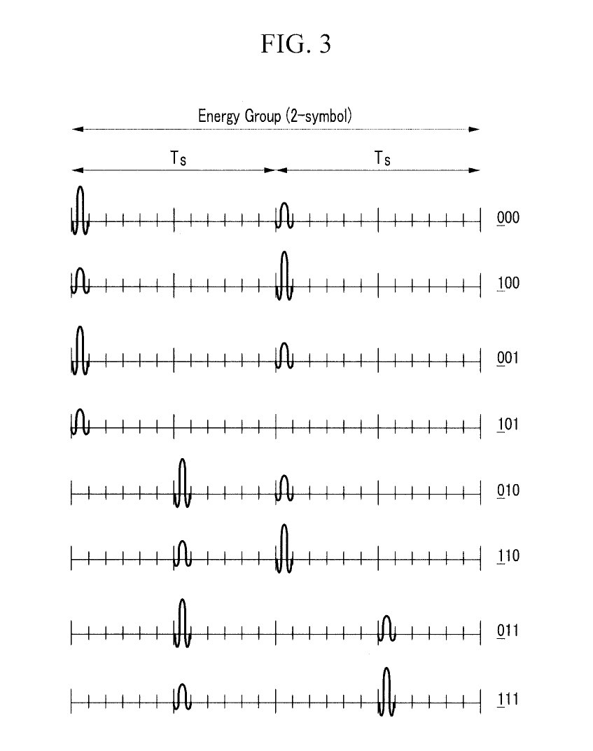

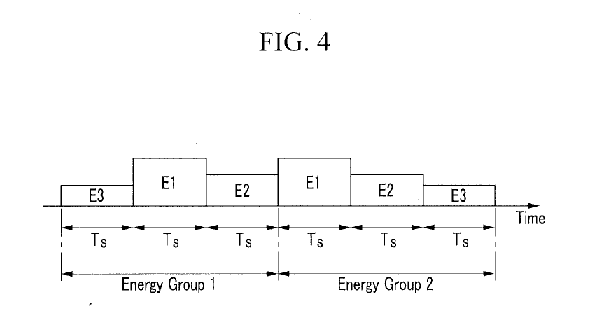

Hereinafter, in exemplary embodiments of the present invention, a block-coded group modulation method based not on the energy sizes of signals as described above but on the sequence of energy sizes of the signals is described in detail with reference to FIGS. 3 and 4.

It is to be noted that the sequence according to the exemplary embodiment of the present invention is based on a sequence according to the size of a pulse corresponding to signal energy.

FIG. 3 is a diagram showing an example in which two symbols are subject to group modulation on the basis of a block-coded group modulation method according to an exemplary embodiment of the present invention, and FIG. 4 is a diagram showing an example in which consecutive signals are modulated on the basis of the block-coded group modulation method according to an exemplary embodiment of the present invention.

In the block-coded group modulation method according to the exemplary embodiment of the present invention, an n+log₂ n! number of bits generated on the basis of the sequence of signal energy sizes by grouping n bits can be transmitted. That is, the block-coded group modulation method based on the sequence of signal energy sizes according to the exemplary embodiment of the present invention can be used to transmit more data than data that are transmitted using the GPPM method during the same period.

Referring to FIG. 3, in the case in which two symbols are grouped, a total of 3 bits can be transmitted during two symbol (energy group, 2-symbol) (2Tₛ) sections.

More particularly, in the case in which each symbol section is divided into two sections like the PPM method, 2 bits can be transmitted during the two symbol (energy group, 2-symbol) sections.

Next, information is further added to bits generated on the basis of the sequence in the size of pulses corresponding to signal energy, transmitted in the first section and the second section, and then transmitted.

Here, information indicated by an underline in FIG. 3 is an information bit that can be additionally transmitted according to the sequence of signal energy sizes. It is assumed that signal energy sizes, for example E1 and E2, exist. The number of cases according to the sequence of signal energy sizes is 2 (i.e., [E1, E2] and [E2, E1]). Accordingly, an information bit generated on the basis of the number of cases according to the sequence of signal energy sizes is 1 bit (log₂ 2=1). In other words, during the two symbol (2Tₛ) sections, a total of 3 bits, including 2 bits in which information can be transmitted like the PPM method and the additional 1 bit generated on the basis of the number of cases according to the sequence of signal energy sizes, can be transmitted.

In the exemplary embodiment of the present invention, a receiving termination receives a signal including information bits generated on the basis of the number of cases according to the sequence of signal energy sizes and restores the received signal on the basis of the sequence of an energy size of the signal. Accordingly, complexity can be reduced.

More particularly, when a receiving termination restores a received signal, the size of the signal differs according to the distance between a transmitting termination and the receiving termination or wireless environments. In this case, the receiving termination becomes complicated because information has to be restored on the basis of a proper data rate. However, in the case in which information is loaded on bits generated on the basis of the number of cases according to the sequence of signal energy sizes, the information is not included in the energy size itself, and the information can be restored by determining only the sequence of energy sizes of signals received during a grouped section. Accordingly, the receiving termination can become simple.

That is, in the block-coded group modulation method based on the sequence of signal energy sizes according to the exemplary embodiment of the present invention, information is not loaded on the energy size of a signal itself, but is additionally loaded on a bit generated on the basis of the number of cases according to the sequence of signal energy sizes, which has been added to bits generated by grouping n bits.

Referring to FIG. 4, in the case in which three symbols are grouped, a total of 5 bits can be transmitted during three symbol (energy group, 3-symbol) (3Tₛ) sections.

In the case in which each symbol section is divided into two sections like the PPM method, 3 bits can be transmitted during three symbol sections.

Here, the number of cases according to the sequence of signal energy sizes is 6 (3!).

It is assumed that signal energy sizes include, for example, E1, E2, and E3. Here, the number of cases according to the sequence of the signal energy sizes is 6 (i.e., [E1, E2, E3], [E1, E3, E2], [E2, E1, E3], [E2, E3, E1], [E3, E1, E2], and [E3, E2, E1]). Four of the six cases are selected. Thus, information bits generated on the basis of the number of cases according to the sequence of signal energy sizes are 2 bits. That is, the 2 bits are added to 3 bits, and so a total of 5 bits are transmitted during the three symbol (3Tₛ) sections.

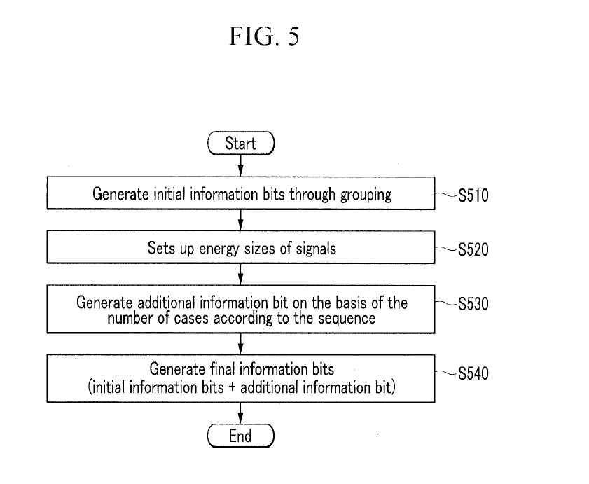

A block-coded group modulation method based on the sequence of the energy sizes of signals is described in detail below with reference to FIG. 5.

FIG. 5 is a flowchart schematically illustrating the block-coded group modulation method according to an exemplary embodiment of the present invention.

Referring to FIG. 5, a transmitter using the block-coded group modulation method generates initial information bits of n bits by grouping an externally inputted payload data bit stream by n bits at step S510.

More particularly, the transmitter groups at least one bit of the payload data bit stream into one group and generates the one group as one transmission unit (i.e., a symbol). For example, during two generated symbol (energy group, 2-symbol) sections, in the case in which each symbol section is divided into two sections, the transmitter generates initial information bits of 2 bits.

Next, the transmitter sets up the size of a pulse corresponding to signal energy (i.e., signal energy size) that is transmitted in the two sections at step S520. For example, the set signal energy size can include E1 and E2.

The transmitter generates an additional information bit on the basis of the number of cases according to the sequence of the signal energy sizes at step S530. In the case in which the signal energy sizes are E1 and E2, the number of cases according to the sequence of the signal energy sizes are [E1, E2] and [E2, E1]. The generated information bit is log₂ 2=1 (i.e., 1 bit).

The transmitter generates final information bits by additionally inserting the additional information bit into the initial information bits at step S540.

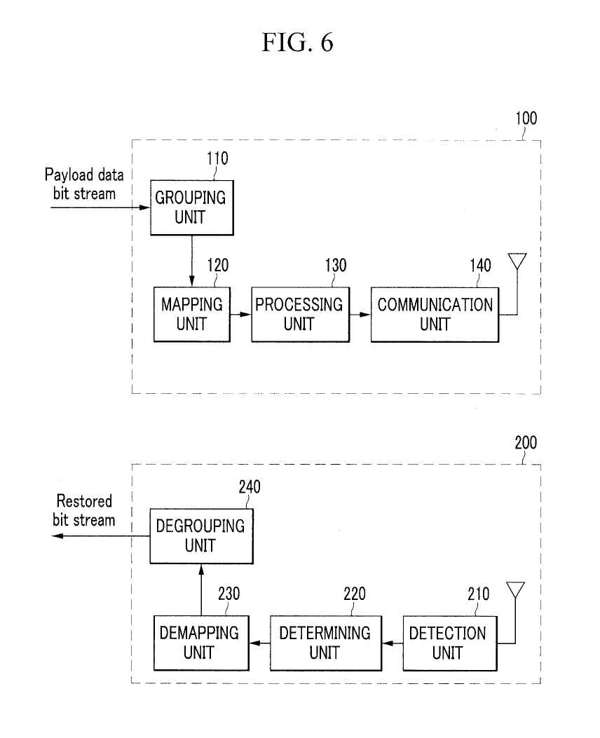

A transmitter and a receiver using the block-coded group modulation method based on the sequence of signal energy sizes is described in detail below with reference to FIG. 6.

FIG. 6 is a block diagram showing a transmitter and a receiver according to an exemplary embodiment of the present invention.

Referring to FIG. 6, the transmitter 100 includes a grouping unit 110, a mapping unit 120, a processing unit 130, and a communication unit 140. The receiver 200 includes a detection unit 210, a determining unit 220, a demapping unit 230, and a degrouping unit 240.

A portion including actual information (i.e., a payload data bit stream) is inputted to the transmitter 100.

The grouping unit 110 groups the inputted payload data bit stream by n bits and generates one group as one transmission unit (i.e., a symbol).

More particularly, the grouping unit 110 classifies a symbol section into an n number of sections and generates initial information bits of n bits. The grouping unit 110 sets up the size of a pulse corresponding to signal energy (i.e., a signal energy size) that is transmitted in the n sections, and generates an additional information bit on the basis of the number of cases according to the sequence of signal energy sizes.

Next, the grouping unit 110 generates final information bits by additionally inserting the additional information bit into the initial information bits, thus generating a symbol including the final information bit.

The mapping unit 120 maps the final information bits constituting the symbol to the sequence to determine an energy level, and converts the symbol into a specific sequence. Here, the sequence to determine the energy level is one of sequences to determine the previously defined energy size of a certain signal.

The processing unit 130 shapes a pulse in response to the specific sequence and generates an impulse signal by changing the energy sizes of transmission signals. Here, the transmitter changes the energy sizes of the transmission signals on the basis of a pulse (i.e., an energy level) during a certain period in response to the specific sequence.

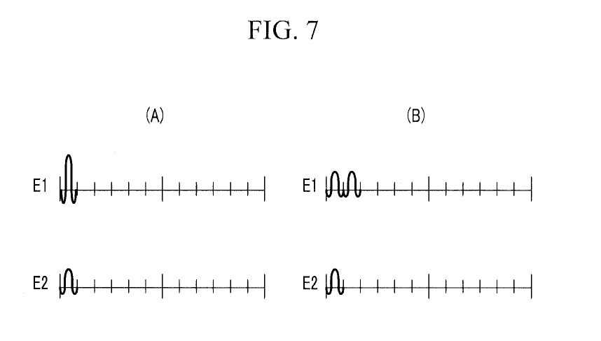

The communication unit 140 transmits the transmission signals, changed by the processing unit 130, to the receiver 200 on the basis of the sequence of different energy sizes. The method of outputting the transmission signals on the basis of the sequence of different energy sizes can include, as shown in FIG. 7, a method (A) of making the pulse sizes of the transmission signals different and a method (B) of making the number of pulses that are repeatedly transmitted different and are corresponding to the transmission signals.

Meanwhile, the receiver 200 restores the payload data bit stream from the signal received from the transmitter 100.

More particularly, the detection unit 210 detects pieces of pulse energy in pulse sections included in the transmission signals received from the transmitter 100.

The determining unit 220 extracts a value of {0,1} by determining a bit for the pulse energy detected in each of the pulse sections.

The demapping unit 230 demaps the result of the determining unit 220 on the basis of the energy sequence.

The degrouping unit 240 restores the payload data bit stream by degrouping the demapping result.

The transmitter using the block-coded group modulation method according to the exemplary embodiment of the present invention does not load information on the energy size itself, but rather loads information on the sequence of the energy sizes. Accordingly, the receiver can easily demodulate information because it has to only restore the sequence of energy sizes of signals.

In accordance with the exemplary embodiment of the present invention, the block-coded group modulation method based on the sequence of signal energy can increase the data throughput by increasing the number of cases according to the sequence of signal energy sizes.

Further, information about signal energy sizes is not loaded, but information about bits generated on the basis of the number of cases according to the sequence of energy sizes is loaded. Accordingly, since a receiving termination only has to restore the sequence of energy sizes, information can be easily demodulated.

Further, the block-coded group modulation method according to the exemplary embodiment of the present invention can be used as a method of grouping multiple symbols and transferring information according to an energy sequence between corresponding symbols, irrespective of a modulation method used by each symbol. That is, the block-coded group modulation method according to the exemplary embodiment of the present invention can be independently used by only loading information on the energy sequence, or can be used together with another modulation method.

The exemplary embodiments of the present invention are not only implemented using the method and apparatus, but can be implemented using a program for realizing a function corresponding to the construction according to the exemplary embodiment of the present invention or a recording medium in which the program is recorded. Such implementations can be readily implemented by those skilled in the art from the description of the above-described exemplary embodiments.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. A block-coded group modulation method, the method comprising:
generating a symbol by grouping at least one bit of a data bit stream into one group;
classifying the symbol into an n number of sections and generating an n number of initial information bits;
setting a size of a pulse corresponding to signal energy transmitted through each of the n sections;
generating an additional information bit on the basis of a number of cases according to a sequence of the sizes; and
generating final information bits by inserting the additional information bit into the initial information bits.

2. The method of claim 1, wherein the sequence is based on a size of the pulse corresponding to the signal energy.

3. The method of claim 1, wherein generating the final information bits further includes
generating transmission signals corresponding to the final information bits; and
outputting the transmission signals with different pulse sizes or outputting the transmission signals with a different number of pulses that are corresponding to the transmission signals and repeatedly transmitted.

4. A transmitter using a block-coded group modulation method, the transmitter comprising:
a grouping unit for generating a symbol by grouping at least one bit of a data bit stream into one group and generating final information bits by inserting an additional information bit into initial information bits, generated by classifying the symbol into an n number of sections, on the basis of a sequence of a size of a pulse corresponding to signal energy transmitted through each of the n sections;
a mapping unit for mapping at least one bit included in the final information bits, and the sequence;
a processing unit for changing energy sizes of transmission signals corresponding to the mapping result; and
a communication unit for outputting the transmission signals according to the sequence of the energy sizes.

5. The transmitter of claim 4, wherein the grouping unit
sets up the size of the pulse corresponding to the signal energy transmitted through each of the n sections, and generates the additional information bit on the basis of a number of cases according to the sequence of the sizes.

6. The transmitter of claim 4, wherein the sequence is based on a size of the pulse corresponding to the signal energy.

7. The transmitter of claim 4, wherein the sequence determines the energy size of a signal.

8. The transmitter of claim 4, wherein the communication unit
outputs the transmission signals with different pulse sizes.

9. The transmitter of claim 4, wherein the communication unit
outputs the transmission signals with a different number of pulses that are repeatedly transmitted and are corresponding to the transmission signals.

10. A receiver for receiving a signal from a transmitter using a block-coded group modulation method based on a sequence of signal energy, the receiver comprising:
a detection unit for detecting pulse energy in each of pulse sections included in the received signal;
a determining unit for determining a bit for the pulse energy detected in the pulse section;
a demapping unit for demapping the determined bit on the basis of the sequence of signal energy; and
a degrouping unit for restoring a data bit stream on the basis of the demapping result.

11. The receiver of claim 10, wherein the degrouping unit extracts final information bits, including initial information bits and an additional information bit, on the basis of the demapping result, estimates a number of cases according to the sequence of sizes on the basis of the additional information bit, and estimates a size of the pulse corresponding to the signal energy on the basis of the number of cases.
